(19) United States
(12) Patent Application Publication
(10) Pub. No.: US 2018/0182962 A1
(43) Pub. Date: Jun. 28, 2018

(54) ORGANIC PHOTOELECTRIC CONVERSION DEVICE AND IMAGING APPARATUS INCLUDING THE SAME

(71) Applicant: KABUSHIKI KAISHA TOSHIBA, Minato-ku (JP)

(72) Inventors: Isao TAKASU, Setagaya (JP); Atsushi WADA, Kawasaki (JP); Yuko NOMURA, Kawasaki (JP); Machiko ITO, Yokohama (JP); Fumihiko AIGA, Yokohama (JP)

(73) Assignee: KABUSHIKI KAISHA TOSHIBA, Minato-ku (JP)

(21) Appl. No.: 15/125,492

(22) PCT Filed: Aug. 6, 2015
(86) PCT No.: PCT/JP2015/072394

§ 371 Date: Sep. 12, 2016

(30) Foreign Application Priority Data
Sep. 18, 2014 (JP) 2014-190270

(51) Int. Cl. H01L 51/00; C07F 5/02

(52) U.S. Cl. CPC H01L 51/008; H01L 27/307; C07F 5/022

(57) ABSTRACT

An organic photoelectric conversion device of the embodiment includes an anode, a cathode, and an organic photoelectric conversion layer provided between the anode and the cathode. The organic photoelectric conversion layer contains a compound represented by the following general formula (1).

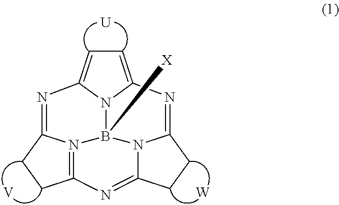

[In the general formula (1), U, V, and W each independently represents a nitrogen-containing 6-membered aromatic ring which may have a substituent or a benzene ring which may have a substituent, at least one of U, V and W represents the nitrogen-containing 6-membered aromatic ring which may have a substituent, X represents any one of a halogen atom, a hydroxyl group, a carboxyl group, an alkyl group which may have a substituent, an aryl group which may have a substituent, an alkoxy group which may have a substituent, and an aryloxy group which may have a substituent.]

### CROSS-REFERENCE TO RELATED APPLICATION

This application is based upon and claims the benefit of priority from Japanese Patent Application No. 2014-190270, filed Sep. 18, 2014, the entire contents of which are incorporated herein by reference.

### FIELD

Embodiments described herein relate generally to an organic photoelectric conversion device and an imaging apparatus including the same.

### BACKGROUND

An organic photoelectric conversion device includes the basic structure in which a photoelectric conversion layer formed of an organic semiconductor material is sandwiched between two electrodes, and at least one of the two electrodes is a transparent electrode.

When using an organic photoelectric conversion device as an imaging device, an exciton, which is generated in a photoelectric conversion layer absorbing a light, is separated into an electron and a hole through bias voltage. These electron and hole can move in a photoelectric conversion layer, any of an electron and a hole reaching electrodes is withdrawn as a signal.

Conventionally, a silicon photodiode is used as an imaging device. In the imaging device using a silicon photodiode, a color filter is indispensable in order to obtain wavelength selectivity. It is one of the features of the organic photoelectric conversion device that an absorption wavelength of an organic photoelectric conversion device is different depending on an organic material and it is possible to selectively absorb a light having a wavelength of a red color, a blue color or a green color. Thus, an organic photoelectric conversion device has the advantage of omitting a color filter.

As the organic photoelectric conversion device, which has an absorption selectivity of green light and exhibits a high photoelectric conversion characteristic, reported is the organic photoelectric conversion device including subphthalocyanine (hereinafter, may be referred to as “SubPc”) in the organic photoelectric conversion layer.

The compound, in which a part of the carbon atoms constituting the benzene ring of SubPc is substituted by a nitrogen atom, is known.

However, the peak wavelength of light absorption of SubPc is on slightly longer wavelength side in a green color of an image sensing device. An organic photoelectric conversion material having a peak wavelength on the shorter wavelength side than the peak wavelength of light absorption of SubPc is required.

### BRIEF DESCRIPTION OF DRAWINGS

FIG. 1 is a cross-sectional view showing an organic photoelectric conversion device of the 1st embodiment.

FIG. 2 is a cross-sectional view showing an organic photoelectric conversion device of the 2nd embodiment.

FIG. 3 is a schematic diagram showing the imaging apparatus of the embodiments.

FIG. 4 is a graph showing the results of measurement of the optical absorption spectra of the compound 3, compound 7 and SubPc.

### DETAILED DESCRIPTION

An organic photoelectric conversion device of the embodiment includes an anode, a cathode and an organic photoelectric conversion layer provided between the anode and the cathode. The organic photoelectric conversion layer contains a compound represented by the following general formula (1).

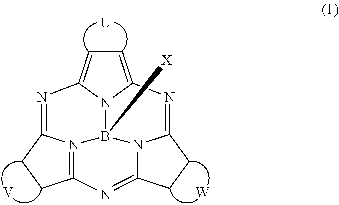

[In the general formula (1), U, V, and W each independently represents a nitrogen-containing 6-membered aromatic ring which may have a substituent or a benzene ring which may have a substituent, at least one of U, V, and W represents the nitrogen-containing 6-membered aromatic ring which may have a substituent, X represents any one of a halogen atom, a hydroxyl group, a carboxyl group, an alkyl group which may have a substituent, an aryl group which may have a substituent, an alkoxy group which may have a substituent, and an aryloxy group which may have a substituent.]

Hereinafter, an embodiment of the present invention is described with reference to Drawings.

### First Embodiment

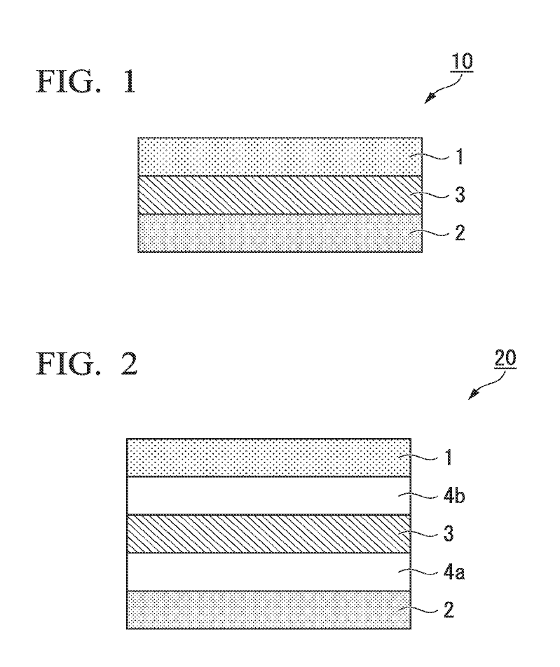

FIG. 1 is a sectional view showing an organic photoelectric conversion device 10 of the 1st embodiment.

The organic photoelectric conversion device 10 includes the cathode 1, the anode 2, and the organic photoelectric conversion layer 3 provided between the cathode 1 and the anode 2.

The cathode 1 is selected in consideration of the adhesion to an adjacent material, the energy level, and stability, etc., but there is no particular limitation. As the material of the cathode 1, it is possible to use, for example, a metal, an alloy, a metal oxide, an electroconductive compound, and a mixture thereof.

Examples of the material of the cathode 1 include metals such as an indium tin oxide (ITO), dopant-containing SnO₂, an aluminum zinc oxide (AZO) obtained by adding Al in ZnO as a dopant, a gallium zinc oxide (GZO) obtained by adding Ga in ZnO as a dopant, and indium zinc oxide (IZO) obtained by adding In in ZnO as a dopant, CdO, TiO₂, CdIn₂O₄, InSbO₄, Cd₂SnO₂, Zn₂SnO₄, MgInO₄, CaGaO₄, TiN, ZrN, HfN, LaB₆, W, Ti, and Al. Further, examples of the material of the cathode include alloys and metal oxides containing the above-mentioned metal. Also, examples of the material of the cathode 1 include an electroconductive polymer such as PEDOT: PSS, a polythiophene compound, and a polyaniline compound; a nano carbon material such as a carbon nanotube and graphene; and an electroconductive compound such as Ag nanowire.

The anode 2 is appropriately selected from the same materials as for the cathode 1 in consideration of the adhesion to an adjacent material, the energy level, and stability, etc.

At least one of the cathode 1 and the anode 2 are preferably transparent. As the material of the non-transparent electrode, it is possible to use W, Ti, TiN, and Al, etc.

A bias voltage is applied to the cathode 1 and the anode 2 so as to facilitate the withdrawal of charge. When using a hole as a signal, a charge from the anode is read out, and when using an electron as a signal, a charge from the cathode is read out.

The organic photoelectric conversion layer 3 includes a compound represented by the general formula (1).

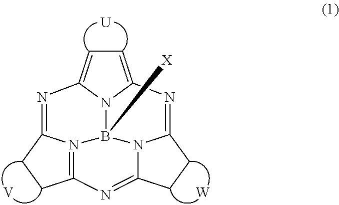

[In the general formula (1), U, V, and W each independently represents a nitrogen-containing 6-membered aromatic ring which may have a substituent or a benzene ring which may have a substituent, at least one of U, V, and W represents the nitrogen-containing 6-membered aromatic ring which may have a substituent, X represents any one of a halogen atom, a hydroxyl group, a carboxyl group, an alkyl group which may have a substituent, an aryl group which may have a substituent, an alkoxy group which may have a substituent, and an aryloxy group which may have a substituent.]

In other words, in the compound represented by the general formula (1), a part of the carbon atoms constituting the benzene ring of SubPc has the structure substituted with a nitrogen atom.

Herein, “a functional group may have a substituent group” refers to both of a functional group having no substituent group and a functional group having a substituent group.

Examples of the compound represented by the general formula (1) include a compound in which all of U, V, and W are a nitrogen-containing 6-membered aromatic ring which may have a substituent; a compound in which two of W, U, V, and W are a nitrogen-containing 6-membered aromatic ring which may have a substituent group, and the remaining one is a benzene ring which may have a substituent group; and a compound in which one of U, V, and W is a nitrogen-containing 6-membered aromatic ring which may have the substituents, and the remaining two are a benzene ring which may have a substituent.

Among these, it is preferable to use a compound in which one or two of W, U, V, and W are a nitrogen-containing 6-membered aromatic ring which may have a substituent group, and the remainder is a benzene ring which may have a substituent group. It is more preferable to use a compound in which one of U, V, and W is a nitrogen-containing 6-membered aromatic ring which may have the substituents, and the remaining two are a benzene ring which may have a substituent.

Further, the nitrogen-containing 6-membered aromatic ring which may have a substituent preferably includes 1-3 nitrogen atoms, more preferably includes 1-2 nitrogen atoms, and much more preferably includes only 1 nitrogen atom.

Examples of the nitrogen-containing 6-membered aromatic ring which may have a substituent include a triazine ring, a pyrimidine ring, a pyridazine ring, a pyrazine ring, and a pyridine ring. Among these, a pyrimidine ring, a pyridazine ring, a pyrazine ring, and a pyridine ring are preferable, and a pyridine ring is more preferable.

Examples of the compound represented by the general formula (1) include a compound in which all of U, V, and W are a pyridine ring; a compound in which all of W, U, V, and W is pyrazine ring; a compound in which all of W, U, V, and W is pyridazine ring; a compound in which two of W, U, V, and W are pyridine ring, and the remaining one is a benzene ring; a compound in which one of W, U, V, and W is pyridine ring, and the remaining two are a benzene ring; a compound in which two of W, U, V, and W are pyrazine ring, and the remaining one is a benzene ring; and a compound in which one of W, U, V, and W is pyrazine ring, and the remaining two are a benzene ring.

Among these, a compound in which one or two of U, V, and W are pyridine ring, and the remaining are benzene ring, is preferable.

Examples of the substituents represented by U, V, and W (hereinafter, may be referred to as a “substituent group T”) include a halogen atom or an alkyl group having 1-20 carbon atoms.

Examples of the halogen atom of the substituent group T include a fluorine atom, a chlorine atom, a bromine atom and an iodine atom, and a chlorine atom is preferable.

The alkyl group having 1-20 carbon atoms in the substituent group T may be linear or branched. Examples of the alkyl group having 1-20 carbon atoms include a methyl group, an ethyl group, a propyl group, a butyl group, a pentyl group, a hexyl group, heptyl group, octyl group, nonyl group, decyl group, undecyl group, dodecyl group, and octadecyl group. Among the alkyl group having 1-20 carbon atoms, an alkyl group having 1-8 carbon atoms is preferred as the substituent T.

X in the general formula (1) is any one of a halogen atom, a hydroxyl group, a carboxyl group, an alkyl group which may have a substituent group, an aryl group which may have a substituent group, an alkoxy group which may have a substituent group, and an aryloxy group which may have a substituent group.

Examples of the halogen atom in X include a fluorine atom, a chlorine atom, a bromine atom and an iodine atom, and a chlorine atom is preferable.

Examples of the alkyl group in X include an alkyl group having 1-20 carbon atoms. An alkyl group having 1-20 carbon atoms may be linear or branched. Examples of the alkyl group having 1-20 carbon atoms are a methyl group, an ethyl group, a propyl group, a butyl group, a pentyl group, a hexyl group, a heptyl group, an octyl group, a nonyl group, a decyl group, an undecyl group, a dodecyl group, and an octadecyl group. Among the alkyl group having 1-20 carbon atoms, an alkyl group having 1-8 carbon atoms is preferred in X. These alkyl groups may have a substituent group such as an aryl group.

Examples of the aryl group in X include an aryl group having 6-30 carbon atoms. Examples of the aryl group having 6-30 carbon atoms include a phenyl group, a naphthyl group and an anthranyl group. These aryl groups may have a substituent group. As the aryl group having a substituent group, a perfluorophenyl group is exemplified.

Examples of the alkoxy group in X include an alkoxy group having 1-20 carbon atoms. The alkoxy group having 1-20 carbon atoms may be linear or branched. Examples of the alkoxy group having 1-20 carbon atoms include a methoxy group, an ethoxy group, a propoxy group, a butoxy group, an octyloxy group, a nonyloxy group, an decyloxy group, an undecyloxy group, a dodecyloxy group, and an octadecyl group. Among the alkoxy group having 1-20 carbon atoms, an alkoxy group having 1-8 carbon atoms is preferred in X. These alkoxy groups may have a substituent group such as an aryl group.

Examples of the aryloxy group in X include an aryloxy group having 6-30 carbon atoms. Examples of the aryloxy group having 6-30 carbon atoms include a phenyl group, a naphthyloxy group, and an anthranyloxy group. These aryloxy groups may have a substituent group. As the aryloxy group having a substituent group, a perfluorophenyloxy group, etc. is exemplified.

Examples of the compound represented by the general formula (1) include the following compounds 1-10.

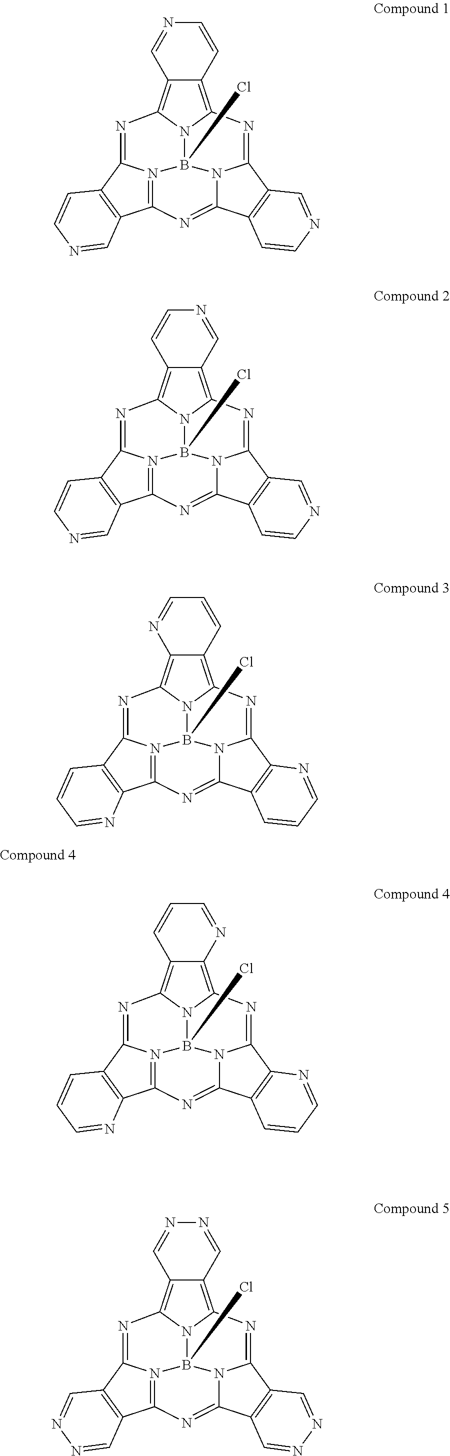

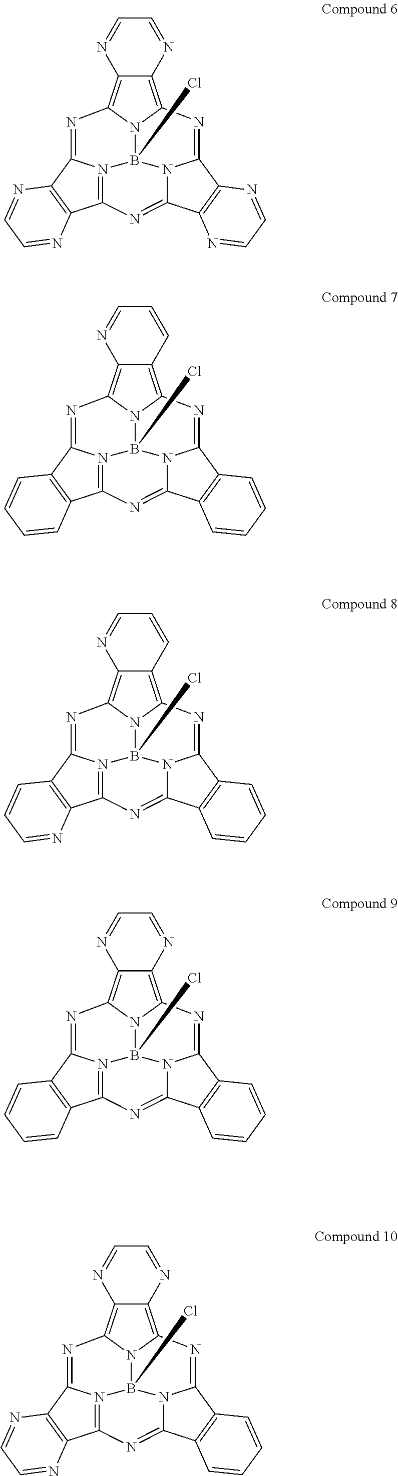

The content of the compound represented by the general formula (1) of the organic photoelectric conversion layer is preferably 10-90 mass %, and more preferably 40-60 mass %.

If the content of the compound represented by the general formula (1) of an organic photoelectric conversion layer is not less than the lower limit, the photoelectric conversion efficiency is likely to be increased. Further, if the content of the compound represented by the general formula (1) of an organic photoelectric conversion layer is not more than the upper limit value, the photoelectric conversion efficiency is likely to be increased.

The organic photoelectric conversion layer 3 may include compounds other than the compounds represented by the general formula (1). Examples of such compound include a quinacridone derivative, a perylene tetracarboxylic acid diimide derivative, and a subphthalocyanine derivative other than the compounds represented by the general formula (1).

By containing such compounds in the organic photoelectric conversion layer 3, it is possible to improve the photoelectric conversion efficiency.

The mass ratio of the compound represented by the general formula (1) in the organic photoelectric conversion layer and the other compounds is preferably from 9/1 to 1/9, and more preferably from 6/4 to 4/6.

When the compound represented by the general formula (1) is contained in the organic photoelectric conversion layer, it is possible to enhance the absorption selectivity for a green light.

Table 1 shows the shift amounts of the light absorption peak wavelengths of the compounds 1-10 with respect to the light absorption peak wavelength of SubPc. The light absorption peak wavelengths of the respective compounds were calculated by the DFT (Density functional theory).

The shift amounts shown in Table 1 are the shift amounts (nm) of the light absorption peak wavelengths of the compounds 1-10 with respect to the light absorption peak wavelength (566 nm) of SubPc. The minus of the shift amount in the table means that the light absorption peak wavelengths of compounds 1-10 is shifted from the light absorption peak wavelength of SubPc to the shorter wavelength side.

TABLE 1

| Compound | Shift Amount (nm) |
|---|---|
| 1 | −3.8 |
| 2 | −11.6 |
| 3 | −22.3 |
| 4 | −19.2 |
| 5 | −16.7 |
| 6 | −27.9 |
| 7 | −8.6 |
| 8 | −16.1 |
| 9 | −7.5 |
| 10 | −14.6 |

As shown in Table 1, according to the calculation using the DFT, the light absorption peak wavelengths of compounds 1-10 is shifted from the light absorption peak wavelength of SubPc to the shorter wavelength side.

Therefore, it is expected that, by containing the compound represented by the general formula (1) in the organic photoelectric conversion layer 3, it is possible to enhance the absorption selectivity for the green light more than that of the organic photoelectric conversion layer using SubPc.

Among the compounds 1-10, in terms of excellent green light-absorbing selectivity and the easiness of synthesis, compound 3, compound 7, and compound 8 are preferred. Also, in terms of the easiness of suppressing the absorption of a blue light, compound 7 is more preferred.

Herein, the compound represented by the general formula (1) can be used singly or in combination of two or more.

When it is desired to further enhance the photoelectric conversion efficiency, it is effective to modify the organic photoelectric conversion layer so as to have the structure (bulk heterojunction) obtained by mixing a material which mainly transport an electron and a material which mainly transport a hole, or the stacked structure of these. The stacked structure is the structure in which a material which mainly transport an electron and a material which mainly transport a hole are stacked.

The organic photoelectric conversion layer 3 may have the structure in which the compounds 1-10 or the mixture thereof is mixed with the photoelectric conversion material that selectively absorbs the other green color. Also, the organic photoelectric conversion layer may have the stacked structure in which the layer containing the compounds 1-10 or the mixture thereof is stacked with the layer containing the photoelectric conversion material that selectively absorbs the other green color.

The LUMO levels and the HOMO levels of the compound 1, compound 3, compound 5, compound 6 and SubPc were determined by molecular orbital calculation.

The results are shown in Table 2.

TABLE 2

| | LUMO | HOMO |
|---|---|---|
| Compound 1 | 3.53 eV | 6.23 eV |
| Compound 3 | 3.22 eV | 6.06 eV |
| Compound 5 | 4.31 eV | 7.09 eV |
| Compound 6 | 3.64 eV | 6.54 eV |
| SubPc | 2.89 eV | 5.59 eV |

From Table 2, the LUMO levels and the HOMO levels of compound 1, compound 3, compound 5 and compound 6 have respectively the lower energy levels than the LUMO level and the HOMO level of SubPc. Thus, charge separation is improved at the interface between the p-type material (such as quinacridone derivatives) and compound 1, compound 3, compound 5 or compound 6. When using compound 1, compound 3, compound 5 or compound 6 as the photoelectric conversion material, it is possible to obtain the higher photoelectric conversion efficiency than that of SubPc.

The compound represented by the general formula (1) is obtained by a known production method. Examples of the production method of the compound represented by the general formula (1) include the method of reacting the nitrogen-containing 6-membered aromatic ring compound having a dicyano group such as dicyanopyrazine, or mixtures of the nitrogen-containing 6-membered aromatic ring compounds and dicyanobenzene, and the trihalogen boron or trialkyl boron by heating at a predetermined temperature.

The organic photoelectric conversion device 10 is produced by forming the layers of the electrode and the organic photoelectric conversion layer by using a dry film forming method or a wet film forming method. Examples of the dry film forming method include physical vapor deposition methods such as a vacuum deposition method, a sputtering method, an ion plating method and MBE, and a CVD method such as plasma polymerization. Examples of the wet film-forming method include coating methods such as a casting method, a spin coating method, a dipping method and a LB method. Further, each layer may be formed by a printing method such as inkjet printing, screen printing, or by a transfer method such as thermal transfer or laser transfer.

### Second Embodiment

FIG. 2 is a cross-sectional view showing an organic photoelectric conversion device 20 of the 2nd embodiment.

The organic photoelectric conversion device 20 includes the cathode 1, the anode 2, the organic photoelectric conversion layer 3, the electron blocking layer 4a sandwiched between the anode 2 and the organic photoelectric conversion layer 3, and the hole blocking layer 4b sandwiched between the cathode 1 and the organic photoelectric conversion layer 3.

A hole accepting material is preferred as a material for forming the electron blocking layer 4a. As a hole accepting material, it is possible to use, for example, a triarylamine compound, a benzidine compound, a pyrazoline compound, a styryl compound, a hydrazone compound, a triphenylmethane compound, a carbazole compound, a thiophene compound, a phthalocyanine compound, or a condensed aromatic compound (such as a naphthalene derivative, an anthracene derivative, a tetracene derivative, a pentacene derivative, a pyrene derivative, or a perylene derivative). The electron blocking layer 4a can contain the compound represented by the general formula (1).

An electron accepting material is preferred as a material for forming the hole blocking layer 4b. As the electron-accepting material, it is possible to use, for example, an oxadiazole derivative, a triazole compound, an anthraquinodimethane derivative, a diphenyl quinone derivative, bathocuproine, a bathocuproine derivative, bathophenanthroline, a bathophenanthroline derivative, a 1,4,5,8-naphthalene-tetracarboxylic diimide derivative, and naphthalene-1,4,5,8-tetracarboxylic acid dianhydride. The hole blocking layer 4b can contain the compound represented by the general formula (1).

The cathode 1 is the same as in the 1st embodiment. The anode 2 is the same as in the 1st embodiment. The organic photoelectric conversion layer 3 is the same as in the 1st embodiment.

Moreover, the organic photoelectric conversion device 20 can be produced by the same method as in the 1st embodiment.

When using the organic photoelectric conversion device 20 for light-sensing, a dark current flowing through the device in dark causes a noise. Most of the dark current is caused by the charge injected from an electrode by a bias voltage.

Because the organic photoelectric conversion device 20 has the electron blocking layer 4a and the hole blocking layer 4b, the injections of the electron and hole from the respective electrodes are suppressed.

### (Imaging Apparatus)

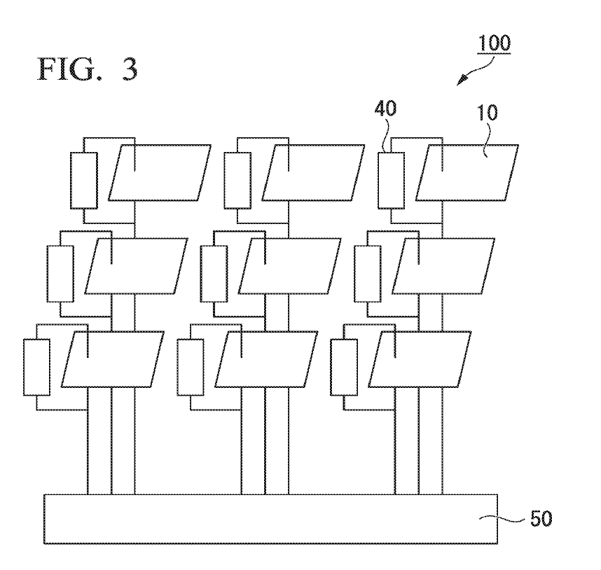

FIG. 3 is a schematic view showing an embodiment of an imaging apparatus.

The imaging apparatus 100 of the embodiment includes the plurality of organic photoelectric conversion device 10, the voltage applying unit 40, and the signal processing unit 50.

In imaging apparatus 100, the organic photoelectric conversion devices 10 are arranged in three rows and three columns. The respective organic photoelectric conversion devices 10 are connected to the voltage applying units 40 and the signal processing units 50.

A voltage is applied to the organic photoelectric conversion device 10 by the voltage applying unit 40. When a reverse bias is applied from the voltage applying unit 40 to the organic photoelectric conversion device 10, an electric field is generated in the organic photoelectric conversion device 10. The electrons and holes generated in the organic photoelectric conversion layer 3 of the organic photoelectric conversion device 10 are respectively attracted to the cathode 1 and the anode 2 by the electric field, and thus, a response speed is improved. The charge separation property of excitons generated in the organic photoelectric conversion layer 3 is improved by the above electric field, and thus, the photoelectric conversion efficiency is improved.

The signal processing unit 50 receives the signals which are photoelectrically converted by the organic photoelectric conversion device 10, and processes the signals.

For example, when arranging the organic photoelectric conversion devices 10 on a plane in n-rows and m-columns, the intensity of light at each point of the organic photoelectric conversion device 10 is sent to the signal processing unit 50 as an electric signal. In the signal processing unit 50, the received electric signal is processed, and is read as image information.

The voltage applied to the organic photoelectric conversion device 10 is not particularly limited. As the applied voltage becomes larger, the electric field generated in the organic photoelectric conversion device 10 becomes greater. For this reason, the photoelectric conversion and the response speed are improved. On the other hand, if the voltage applied is too large, a current flows in an opposite direction of the purpose due to yield phenomenon. For example, it is preferred to apply the voltage by which the electric field generated in the organic photoelectric conversion layer is from 1.0×10⁴ V/cm to 1.0×10⁶ V/cm.

As the imaging apparatus 100, the organic photoelectric conversion device 10 of the 1st embodiment is used, but the imaging apparatus of the embodiment is not limited thereto. For example, as the imaging apparatus 100, it is possible to use the organic photoelectric conversion apparatus 20 of the 2nd embodiment.

In the imaging apparatus 100, the organic photoelectric conversion devices 10 are arranged in three rows and three columns, but the imaging apparatus of the embodiment is not limited thereto. The row number and the column number of the organic photoelectric conversion device 10 are arranged arbitrarily. Alternatively, the organic photoelectric conversion device 10 can be disposed anywhere without arranging.

In the imaging apparatus 100, the voltage applying unit 40 is connected to the respective organic photoelectric conversion device 10, but the imaging apparatus of the embodiment is not limited thereto. For example, wires may be arranged from one voltage applying unit to the respective organic photoelectric conversion devices 10, to thereby simultaneously apply voltages.

Such imaging device 100 is used for a video camera, a digital still camera, or a camera, etc.

As described above, according to at least one of the embodiments, the absorption selectivity for a green light is improved.

### EXAMPLES

Hereinafter, specific examples are described. In accordance with the following Production Example 1 and Production Example 2, compound 3 and compound 7 were prepared.

### Production Example 1

(Production of Compound 3)

To the reaction vessel, 1-chloronaphthalene 20 mL was added, and 2,3-dicyano pyridine (5.2 g, 0.04 mol) was added thereto. The contents of the reaction vessel were cooled to −3° C., and boron trichloride (20.5 mL, 0.02 mol, 1M hexane solution) was added into the reaction vessel under a nitrogen stream. After removing by distillation hexane from the contents of the reaction vessel, the contents of the reaction vessel were heated at 180° C. for 3 hours. Then, 1-chloronaphthalene was removed from the contents of the reaction vessel. The resulting product was extracted with petroleum ether for 24 hours, and then, was extracted with toluene for 2 hours. Further, the product was washed with ethanol, and then, was recrystallized, to thereby obtain compound 3. The yield of compound 3 was 590 mg, and the yield was 10%.

### Production Example 2

(Production of Compound 7)

To the reaction vessel, 1-chloronaphthalene 20 mL was added, and 2,3-dicyano pyridine (1.29 g, 0.01 mol) and 1,2-dicyanobenzene (2.6 g, 0.02 mol) were added thereto. The contents of the reaction vessel were cooled to −3° C., and boron trichloride (20.5 mL, 0.02 mol, 1M hexane solution) was added into the reaction vessel under a nitrogen stream. After removing by distillation hexane from the contents of the reaction vessel, the contents of the reaction vessel were heated at 180° C. for 3 hours. Then, 1-chloronaphthalene was removed from the contents of the reaction vessel. The resulting product was extracted with petroleum ether for 24 hours, and then, was extracted with toluene for 2 hours. Further, the product was washed with ethanol, and then, was separated by silica gel column chromatography and recrystallized, to thereby obtain compound 7. The yield of compound 7 was 219 mg, and the yield was 5%.

(Absorption Selectivity of the Green Light)

For each of compound 3, compound 7, and SubPc which is a comparative component, the absorption spectrum was measured in a solution state.

The absorption spectrum of the dimethylformamide solution of each compound (concentration: about 1×10⁻⁶ mol/L) was measured.

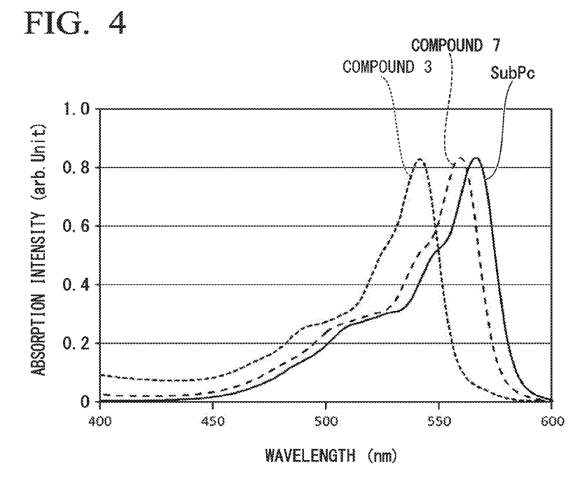

The results of the absorption spectra are shown in FIG. 4. FIG. 4 is a graph showing the measurement results of the light absorption spectrum of the compound 3, compound 7 and SubPc.

As shown in FIG. 4, the peak wavelengths of light absorptions of compound 3 and compound 7 were shifted to the short wavelength side, as compared to the peak wavelength of light absorption of SubPc.

Therefore, it was confirmed that the photoelectric conversion device including a photoelectric conversion layer containing the compound represented by the general formula (1) has the excellent absorption selectivity for a green light as compared with the photoelectric conversion device using SubPc.

It should be noted that this results were consistent with the calculation results by the above-mentioned DFT (Density Functional Theory).

Moreover, the peak wavelength of light absorption of compound 3 was more shifted to the short wavelength side than compound 7. However, it was found that the absorption of the blue light at around 450 nm of compound 3 was greater than that of compound 7 because the absorption wavelength of compound 3 was broad.

Therefore, in terms of the suppression of the absorption of a blue light, compound 7 is preferred.

While certain embodiments have been described, these embodiments have been presented by way of example only, and are note intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

1. An organic photoelectric conversion device comprising:
an anode;
a cathode; and
an organic photoelectric conversion layer provided between the anode and the cathode, wherein
the organic photoelectric conversion layer contains a compound represented by the following general formula (1); 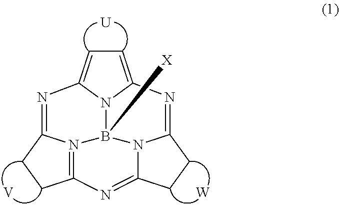
in which in the general formula (1), U, V, and W each independently represents a nitrogen-containing 6-membered aromatic ring which may have a substituent or a benzene ring which may have a substituent, at least one of U, V, and W represents the nitrogen-containing 6-membered aromatic ring which may have a substituent, X represents any one of a halogen atom, a hydroxyl group, a carboxyl group, an alkyl group which may have a substituent, an aryl group which may have a substituent, an alkoxy group which may have a substituent, and an aryloxy group which may have a substituent.

2. The organic photoelectric conversion device according to claim 1, further comprising:
an electron blocking layer provided between the anode and the organic photoelectric conversion layer; and
a hole blocking layer provided between the cathode and the organic photoelectric conversion layer.

3. The organic photoelectric conversion device according to claim 2, wherein any one or both of the electron blocking layer and the hole blocking layer contains the compound represented by the general formula (1).

4. (canceled)
